(19) United States
(12) Patent Application Publication
(10) Pub. No.: US 2019/0355577 A1
(43) Pub. Date: Nov. 21, 2019

(54) METHOD FOR PRINTING MICRO LINE PATTERN USING INKJET TECHNOLOGY

(71) Applicant: UNIJET CO., LTD., Seongnam-si (KR)

(72) Inventor: Seog-soon KIM, Seongnam-si (KR)

(73) Assignee: UNIJET CO., LTD., Seongnam-si (KR)

(21) Appl. No.: 16/411,152

(22) Filed: May 14, 2019

(30) Foreign Application Priority Data
May 16, 2018 (KR) 10-2018-0055746

(51) Int. Cl. H01L 21/02; H01L 21/67; H01L 21/768

(52) U.S. Cl. CPC H01L 21/02288; H01L 21/67248; H01L 2021/60022; H01L 21/76825; H01L 21/76892

(57) ABSTRACT

A method for printing a micro line pattern using inkjet printing, includes: a bump forming process for forming a micro bump that sections a predetermined conductive pattern by inkjet-printing a quick drying liquid on a substrate; and a pattern printing process for printing a conductive pattern according to the predetermined conductive pattern by inkjet-printing a conductive liquid on an area sectioned by the micro bump.

### TECHNICAL FIELD

The present invention relates to a method for printing a micro line pattern using inkjet technology, and more particularly, to a method for printing a micro line pattern using inkjet technology, which is capable of simply manufacture a substrate having a line pattern having a micro width less than about 20 μm by using an inkjet printing method only.

### BACKGROUND ART

A method for printing a conductive pattern using an inkjet technology is developed at the beginning of printed electronic technology, and then a PCB manufacturing technology using a line width in a range from about 80 μm to about 150 μm is developed by using inkjet technology.

However, although the above-described inkjet technology has many advantages, the inkjet technology has not been frequently used in PCB manufacturing. This is because the inkjet technology has a limitation in that a line width with the higher thickness is hardly achieved in PCB, high manufacturing costs are required, and productivity is low in comparison with a screen printing technology.

Because of the above-described reasons, the current inkjet technology is applied in an extremely restricted range such as manufacturing of small quantity batch production PCB products having a line width in a range from about 50 μm to about 80 μm or manufacturing a small quantity of PCB samples.

In recent years, a next generation PCB or semiconductor packaging needed to have a high density interconnect (HDI) board is necessarily manufactured to have a pattern having a micro line width of about 20 μm or less for high integration. However, since the screen printing technology is difficult to be used for highly integrated PCB manufacturing due to low uniformity and integration, the highly integrated PCB or semiconductor packaging is manufactured by using a lithography or a laser method, and particularly, the HDI PCB or semiconductor packaging for mobile devices is manufactured by a high cost manufacturing method such as a lithography or a laser method.

On the other hand, the inkjet printing method may directly print a line without using typical exposure, etching, and plating processes. That is, the inkjet printing method is a patterning technology printing a micro line with a micro-meter width by jetting a solution or a dispersion in a form of several or several tens of droplets in a pico-liter (pl) size through a micro nozzle.

Particularly, a surface condition of the substrate is treated so that a micro line pattern portion has hydrophilic characteristics and the rest portion has hydrophobic characteristics, and then the micro line pattern is formed on the portion having the hydrophilic characteristics with conductive ink. More particularly, the micro line pattern is realized such that the hydrophilic portion and the hydrophobic portion are separately formed through a lithography method or in a method of applying a hydrophobic layer and then applying a conductive material on the hydrophobic pattern using etching treatment with UV light, and then as conductive ink is applied, all the applied ink is collected into a hydrophilic area.

As described above, since the typical inkjet printing method is easy in design change and reduced in manufacturing costs of photomasks, complicated process steps, and manufacturing process time, the inkjet printing method has been increasingly used.

However, the inkjet printing method has a limitation in terms of high manufacturing costs of surface treatment for applying a hydrophobic property/hydrophilic property.

On the other hand, since the inkjet printing method may achieve an ink droplet having a size of 1 pl (diameter of 12.6 μm) due to restriction of a commercialized inkjet head, the micro line pattern having a size of about 20 μm may not be substantially achieved by only using the inkjet technology.

Particularly, when the ink droplet having a size of 1 pl (diameter of 12.6 μm) is jetted and deposited on the surface of the substrate, the ink may be spread into various sizes according to surface energy. In case of a hydrophilic surface energy, which is more general, the ink droplet may have a line width of about three times (35 μm) or four times (47 μm), and in case of a hydrophobic treated surface state, the ink droplet may have a line width of two times (22 μm). However, a line having a line width less than the above-described sizes, which are substantially required in various application fields, may be hardly realized, and furthermore, product manufacturing is more difficult through the above-described processes.

Also, as the ink droplet decreases in size, a thickness of the micro line pattern also decreases, and thus the micro line having a higher thickness is further difficult to be achieved. Although achieved, since a boundary between micro lines is not uniform, the inkjet printing method is hardly applied to substantial application fields due to great transmission losses, especially for high frequency range.

In some cases, the printing may be performed by jetting an ink droplet on a heated substrate and then drying the ink droplet by heat of the substrate. However, when the ink is dried by the heat of the substrate, a head nozzle itself may be clogged due to evaporation (or drying) of a solvent contained in the ink in the nozzle of the head, and thus the printing may exhibit extremely low quality or the printing itself may not be performed successfully.

Also, since the method of heating the substrate causes thermal expansion of the substrate itself and the inkjet head, the accurate positioning of micro line may not be achieved due to errors caused by the thermal expansion.

### PRIOR ART DOCUMENT

Korean Registered Patent No. 10-0833110 (Registration date: May 22 2008)
Korean Registered Patent No. 10-0858722 (Registration date: Sep. 9 2008)
Korean Registered Patent No. 10-1116762 (Registration date: Feb. 8 2012)

### DISCLOSURE OF THE INVENTION

### Technical Problem

The present invention provides a method for printing a micro line pattern using inkjet technology, which is capable of manufacturing a substrate having a pattern with a micro line width of about 20 μm or less by only using an inkjet printing method in a simple manner, and more particularly, a method for printing a micro line pattern using inkjet technology, which is capable of achieving an excellent micro line pattern having a uniform boundary and a high printing precision by adopting a pinning method using UV ink instead of ink drying by heating.

The present invention also provides a method for printing a micro line pattern using inkjet technology, which is capable of realizing a precise position of a micro line and an ink droplet having a smaller micro size by fundamentally preventing a nozzle clogging limitation of a head, which is caused by evaporation (or drying) of a solvent contained in ink in a nozzle of the head due to heat transferred from a heated substrate.

### Technical Solution

An embodiment of the present invention provides a method for printing a micro line pattern using inkjet technology, the method including: a bump forming process for forming a micro bump that sections a predetermined conductive pattern by inkjet-printing a quick drying liquid on a substrate; and a pattern printing process for printing a conductive pattern according to the predetermined conductive pattern by inkjet-printing a conductive liquid on an area sectioned by the micro bump.

In an embodiment, the quick drying liquid may be photocurable ink that is ink-jetted and then gelled by light.

In an embodiment, the quick drying liquid may be hot melt ink that is ink-jetted and then gelled by phase change due to a temperature difference and light.

In an embodiment, the quick drying liquid may have a hydrophobic surface characteristic after dried.

In an embodiment, a surface of the substrate may be hydrophobic-treated.

In an embodiment, the bump forming process may increase a height of the micro bump by repeatedly inkjet-printing the quick drying liquid.

In an embodiment, the pattern printing process may increase a height of the conductive pattern by repeatedly inkjet-printing the conductive liquid.

In an embodiment, each of the inkjet-printing of the quick drying liquid in the bump forming process and the inkjet-printing of the conductive liquid in the pattern printing process may be performed by a drop on demand (DOD) inkjet printing method.

In an embodiment, the method may further include a bump removing process for removing the micro bump formed in the bump forming process after the pattern printing process.

In an embodiment, the bump forming process and the pattern printing process may be performed by an inkjet printing device including: a transfer unit configured to transfer the substrate in one direction; a first head configured to reciprocatingly move in a vertical direction at a front end of a movement direction of the substrate to jet the quick drying liquid; a light irradiation unit installed adjacent to the first head; and a second head installed at a rear end of the movement direction of the substrate to reciprocatingly move in a direction perpendicular to the movement direction of the substrate, thereby jetting the conductive liquid. Here, the bump forming process may be performed such that the quick drying liquid is deposited on the substrate in a state of being ink-jetted by the first head and then gelled by light irradiated from the light irradiation unit, to form the micro bump, the pattern printing process may be performed such that the conductive liquid is ink-jetted between the micro bumps by the second head, to print the conductive pattern, and the micro bump and the conductive pattern may be formed at the same time.

In an embodiment, the first head and the light irradiation unit may be integrated with each other to move together, and the first head, the light irradiation unit, and the second head may be integrated with each other to move together.

In an embodiment, the inkjet printing device may be installed in a enclosed space having a helium gas atmosphere, and the process of forming the micro bump by the quick drying liquid that is ink-jetted from the first head and the process of forming the conductive pattern by the conductive liquid that is ink-jetted between the micro bumps by the second head may be performed under the helium gas atmosphere.

### Advantageous Effects

The above-described present invention has an advantage in that the substrate having excellent position precision is printed by excluding thermal expansion because the pattern having a micro line width of about 20 μm or less is simply printed without heating by using only the inkjet printing method.

Also, as substrate heating is excluded by adopting the pinning method using UV, the excellent micro line pattern having high precision and the uniform boundary may be realized.

Also, when compared with the lithography method, the micro line pattern may be realized with lower manufacturing costs.

Also, the treatment for a wide area may be easily performed. The present invention may be also applied to a narrow (or edge) side surface of a substrate, a substrate having a stepped portion, and substrates made of various kinds of materials having different surface properties, which are not easily treated by the lithography method.

Also, as the inkjet printing process is performed under the helium gas atmosphere, although the head having the same small size nozzle is used, a small ink droplet should achieve faster jetting speed for travelling farther distance under this gas atmosphere, thereby printing a smaller micro line width more accurately.

### BRIEF DESCRIPTION OF THE DRAWINGS

FIG. 1 is a flowchart illustrating a method for printing a micro line pattern using inkjet method according to a first embodiment of the present invention.

FIG. 2 is a flowchart illustrating a method for printing a micro line pattern using inkjet method according to a second embodiment of the present invention.

FIG. 3 is a flowchart illustrating a method for printing a micro line pattern using inkjet method according to a third embodiment of the present invention.

FIG. 4 is a flowchart illustrating a method for printing a micro line pattern using inkjet method according to a fourth embodiment of the present invention.

FIG. 5 is a flowchart illustrating a method for printing a micro line pattern using inkjet method according to a fifth embodiment of the present invention.

FIGS. 6 and 7 are plan configuration views illustrating a schematic configuration of an inkjet printing device for achieving the method for printing a micro line pattern using inkjet method according to the present invention.

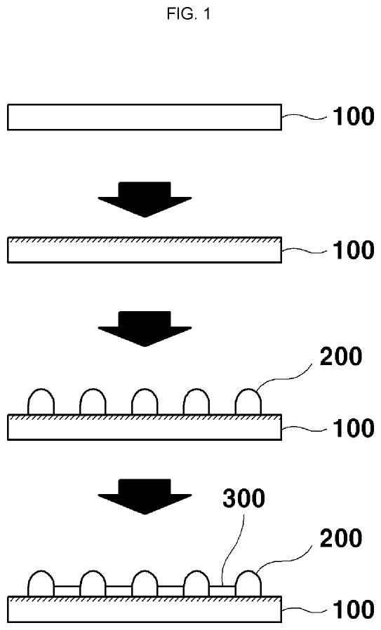

### MODE FOR CARRYING OUT THE INVENTION

The present invention may be carried out in various embodiments without departing from the technical ideas or primary features. Thus, the preferred embodiments of the present invention should be considered in descriptive sense only and are not for purposes of limitation.

It will be understood that although the terms such as ‘first’ and ‘second’ are used herein to describe various elements, these elements should not be limited by these terms.

The terms are only used to distinguish one component from other components. For example, a first element referred to as a first element in one embodiment can be referred to as a second element in another embodiment without departing from the scope of the appended claims.

The word ‘and/or’ means that one or more or a combination of relevant constituent elements is possible.

It will also be understood that when an element is referred to as being “‘connected to” or “engaged with” another element, it can be directly connected to the other element, or intervening elements may also be present.

It will also be understood that when an element is referred to as being ‘directly connected to’ another element, there is no intervening elements.

In the following description, the technical terms are used only for explaining a specific exemplary embodiment while not limiting the present invention. The terms of a singular form may include plural forms unless referred to the contrary.

The meaning of ‘include’ or ‘comprise’ specifies a property, a number, a step, a process, an element, a component, or a combination thereof in the specification but does not exclude other properties, numbers, steps, processes, elements, components, or combinations thereof.

Unless terms used in the present invention are defined differently, the terms may be construed as meaning known to those skilled in the art.

Terms such as terms that are generally used and have been in dictionaries should be construed as having meanings matched with contextual meanings in the art. In this description, unless defined clearly, terms are not ideally, excessively construed as formal meanings.

Hereinafter, embodiments disclosed in this specification is described with reference to the accompanying drawings, and the same or corresponding components are given with the same drawing number regardless of reference number, and their duplicated description will be omitted.

Moreover, detailed descriptions related to well-known functions or configurations will be ruled out in order not to unnecessarily obscure subject matters of the present invention.

A method for printing a micro line pattern using inkjet printing according to a first embodiment of the present invention includes a substrate preparing process, a substrate treatment process, a bump forming process, and a pattern printing process.

The substrate preparing process prepares a substrate on which a micro line pattern is printed.

The substrate may include a substrate used in various application fields requiring a conductive pattern with a micro width of about 20 μm or less, e.g., a substrate for PCB of mobile phones applied with substrate like PCB (SLP), a semiconductor packaging substrate for high density interconnect (HDI) requiring a high level of integration, a substrate for a touch screen panel with minimized bezel, a substrate for micro-LED, and a substrate for fan out wafer level package (FoWLP).

The substrate treatment process allows a surface condition of the substrate to be uniform and also performs a hydrophobic treatment on the surface.

As the surface of the substrate is hydrophobic-treated, an ink area in which ink is adhered to the surface of the substrate may be reduced.

On the other hand, when the substrate prepared in the substrate preparing process already has a hydrophobic feature or has a hydrophobic treated surface, the substrate treatment process may be omitted.

Also, since the hydrophobic surface treatment is an optional process, a substrate that is not hydrophobic-treated may be used.

The bump printing process forms a micro bump for sectioning a predetermined conductive pattern by inkjet-printing a quick drying liquid on the substrate. For example, the inkjet printing of the quick drying liquid may adopt a drop on demand (DOD) inkjet printing method.

Here, the substrate may be maintained at the room temperature without being heated.

The quick drying liquid represents a liquid that is ink-jetted and then rapidly gelled. For example, the quick drying liquid may be a photocurable ink that is rapidly dried by light or a hot melt ink that is rapidly dried through phase change due to a temperature difference and UV light.

For a specific example, as a light irradiation unit for irradiating UV rays is installed adjacent to a jetting nozzle, the photo curable ink jetted through the jetting nozzle is rapidly gelled by the UV rays irradiated from the light irradiation unit, and thus increases in viscosity. Thus, the photocurable ink is prevented from being spread to the side when deposited on the surface of the substrate.

Also, the hot melt ink is heated by a heating unit and jetted in a liquid state through the jetting nozzle, and then exposed to the air to be cooled while being rapidly gelled due to a temperature difference and UV light, thereby increasing in viscosity. Thus, the hot melt ink is prevented from being spread to the side when deposited on the surface of the substrate.

As described above, a feature, in which the quick drying liquid is prevented from being spread to the side when deposited on the surface of the substrate because of the rapid gelling before deposited on the surface of the substrate after being exposed through the jetting nozzle, is referred to as pinning.

Through the hydrophobic treatment of the substrate and the pinning of the quick drying liquid, the micro bump may be formed in a micro-size to have a width of about 5 μm to about 20 μm.

Here, in the quick drying liquid such as the photocurable ink or the hot melt ink, a surface condition after being dried by light desirably has hydrophobic characteristics, so that a conductive liquid in a pattern printing process, which will be described later, is printed only on a predetermined conductive pattern.

The pattern printing process prints a conductive pattern according to a predetermined conductive pattern by inkjet-printing a conductive liquid on an area that is sectioned by the micro bump. For example, a drop on demand (DOD) inkjet printing method may be applied to inkjet printing of the conductive liquid.

The conductive ink includes Ag, Cu, Au, Pt, CNT, AgNW, graphene, graphene oxide, conductive polymer, or a combination thereof.

Particularly, in a state in which the micro bump for sectioning the predetermined conductive pattern is printed through the bump forming process, i.e., a state in which the micro bump is formed on a portion besides the predetermined conductive pattern, the conductive liquid is inkjet-printed on the area sectioned by the micro bump. In other words, the conductive liquid is inkjet-printed on a portion between the micro bumps besides the predetermined conductive pattern.

On the other hand, since the bump is formed by using the quick drying liquid of which a dried surface condition has the hydrophobic characteristics as described above, a dried surface state of the micro bump also has the hydrophobic characteristics. As a result, although a portion of the conductive ink may be inkjet-printed to an upper portion of the bump when the conductive ink is inkjet-printed between the bumps, the conductive ink may flow between the micro bumps to perform excellent pattern formation. The hydrophobic level of the dried bump surface condition may be adjusted by the ink formulation as well as additional surface treatment to meet the printing requirement.

As the conductive ink is dried, a conductive constituent contained in the conductive ink may form the conductive pattern, and the micro bump may function as an insulator that insulates the conductive patterns, which are required to be electrically insulated from each other.

As described above, as the conductive pattern is formed by inkjet-printing the conductive ink between the micro bumps so that each of the micro bumps has a width of about 5 μm to about 20 μm, the conductive pattern may has a width of about 5 μm to about 20 μm.

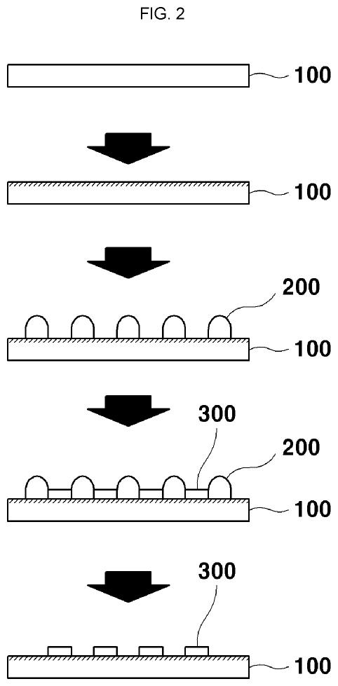

As illustrated in FIG. 2, a method for printing a micro line pattern using inkjet printing according to a second embodiment of the present invention includes a substrate preparing process, a substrate treatment process, a bump forming process, a pattern printing process, and a bump removing process. Here, since the substrate preparing process, the substrate treatment process, the bump forming process, and the pattern printing process of the second embodiment are the same as those of the first embodiment, description for the same processes will be omitted, and only the bump removing process will be described.

The bump removing process strips the micro bump formed in the bump forming process after the pattern printing process.

The quick drying ink liquid is made of an acrylic-based photo-polymer, and when pure water or water containing about 0.5% of NaOH is showered in a spray or water-jet manner toward the micro bump formed of the quick drying liquid made of the above described material, the bump may be easily decomposed and striped, and only the conductive micro pattern may be remained through drying after the micro bump is removed.

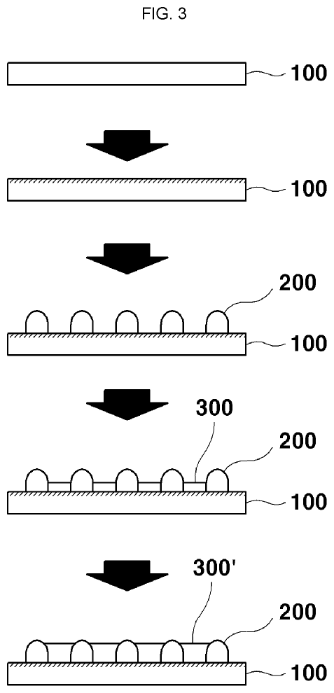

As illustrated in FIG. 3, a method for printing a micro line pattern using inkjet printing according to a third embodiment of the present invention includes a substrate preparing process, a substrate treatment process, a bump forming process, and a pattern printing process. Here, since the substrate preparing process, the substrate treatment process, and the bump forming process of the third embodiment are the same as those of the first embodiment, description for the same processes will be omitted, and only the pattern printing process will be described.

The pattern printing process prints a conductive pattern according to the predetermined conductive pattern by inkjet-printing the conductive liquid on an area sectioned by the micro bump. For example, the inkjet printing of the conductive liquid may adopt a drop on demand (DOD) inkjet printing method, and particularly, as the conductive liquid is repeatedly inkjet-printed, the conductive pattern may increase in height.

The conductive ink includes Ag, Cu, Au, Pt, CNT, AgNW, graphene, graphene oxide, conductive polymer, or a combination thereof.

Particularly, in a state in which the micro bump for sectioning the predetermined conductive pattern is printed through the bump forming process, i.e., a state in which the micro bump is printed on a portion besides the predetermined conductive pattern, the conductive liquid is repeatedly inkjet-printed on the area sectioned by the micro bump.

More particularly, the inkjet printing is performed by repeating a process in which the conductive liquid is primarily inkjet-printed and dried between the micro bumps formed on a portion besides the predetermined conductive pattern, and then the conductive liquid is secondarily inkjet-printed and dried.

As the conductive liquid is repeatedly inkjet-printed, an overall thickness of the conductive pattern may increase to achieve excellent conductive characteristics required by a lot of applications.

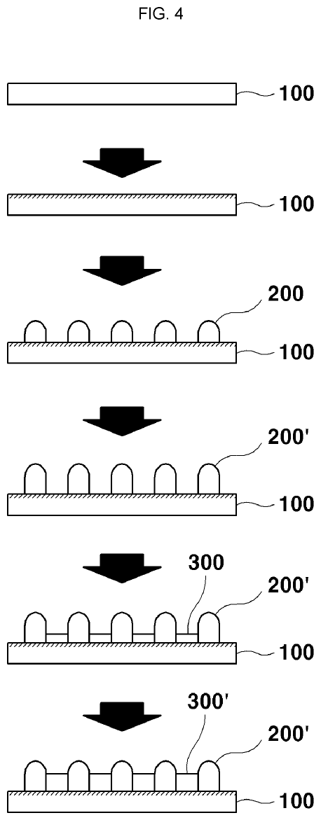

As illustrated in FIG. 4, a method for printing a micro line pattern using inkjet printing according to a fourth embodiment of the present invention includes a substrate preparing process, a substrate treatment process, a bump forming process, and a pattern printing process. Here, since the substrate preparing process and the substrate treatment process of the fourth embodiment are the same as those of the first embodiment, description for the same processes will be omitted, and only the bump forming process and the pattern printing process will be described.

The bump forming process forms a micro bump for sectioning a predetermined conductive pattern by inkjet-printing the quick drying liquid on the substrate. For example, the inkjet printing of the quick drying liquid may adopt a drop on demand (DOD) inkjet printing method, and particularly, as the quick drying liquid is repeatedly inkjet-printed, the micro bump may increase in height.

The quick drying liquid represents a liquid that is inkjet-printed and then rapidly gelled, and is the same as or similar to that of the first embodiment.

As the quick drying liquid is rapidly gelled before deposited on the surface of the substrate after jetted from the jetting nozzle, the quick drying liquid may be prevented from being spread to the side when deposited on the surface of the substrate, and as the quick drying liquid is repeatedly inkjet-printed according to the pattern or the same position by using the above-described pinning technique, the micro bump may increase in height.

The pattern printing process prints a conductive pattern according to a predetermined conductive pattern by inkjet-printing a conductive liquid on an area that is sectioned by the micro bump having the increased height. For example, the inkjet printing of the conductive liquid may adopt a drop on demand (DOD) inkjet printing method. Particularly, as the conductive liquid is repeatedly inkjet printed, the conductive pattern may increase in height, and since detained description for this is the same as that of the third embodiment, detailed description will be omitted.

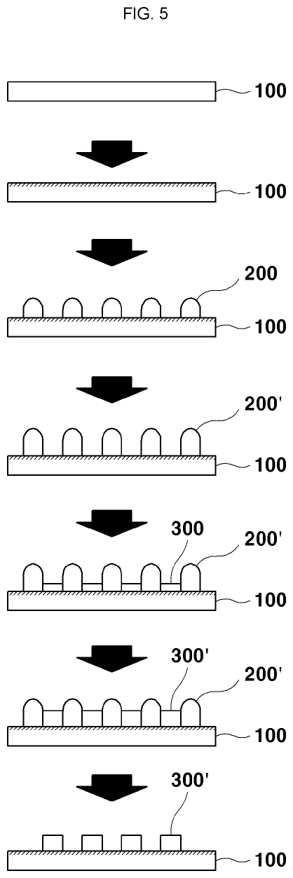

As illustrated in FIG. 5, a method for printing a micro line pattern using inkjet printing according to a fifth embodiment of the present invention includes a substrate preparing process, a substrate treatment process, a bump forming process, a pattern printing process, and a bump removing process. Here, since the substrate preparing process, the substrate treatment process, the bump forming process, and the pattern printing process of the fifth embodiment are the same as those of the fourth embodiment, description for the same processes will be omitted, and only the bump removing process will be described.

The bump removing process removes a micro bump formed in the bump forming process after the pattern printing process. The bump removing process may be performed in the same or similar manner as that of the second embodiment.

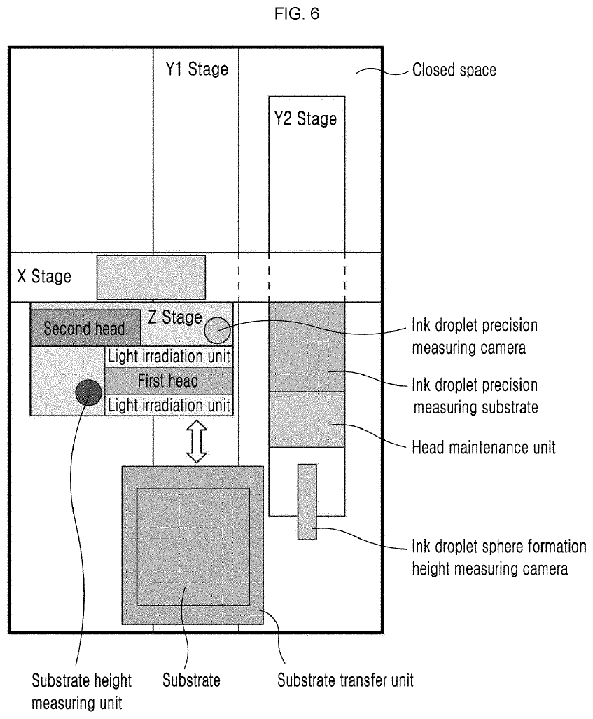

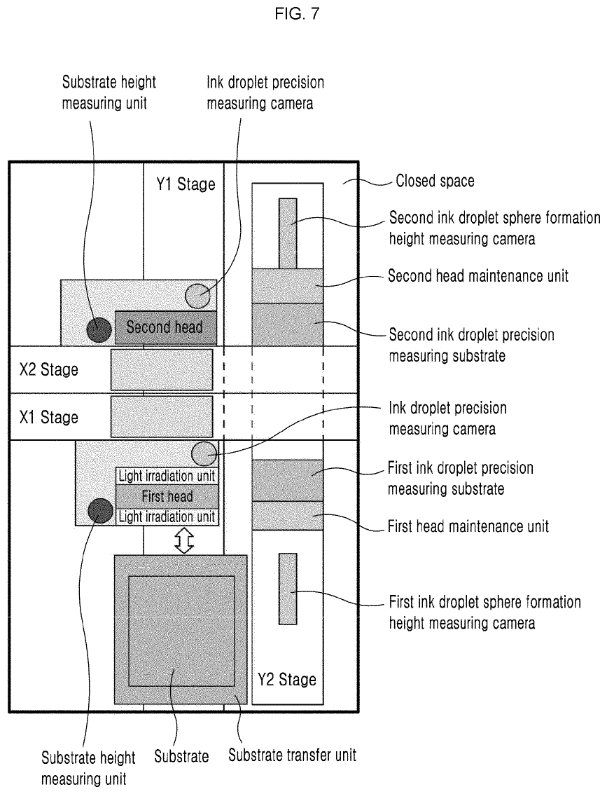

FIGS. 6 and 7 illustrate a schematic configuration of an inkjet printing device for realizing the above-described method for printing a micro line pattern using inkjet printing. An operation of the device will be described with the method for printing a micro line pattern according to the first embodiment.

The inkjet printing device in FIG. 6 is configured such that a first head for jetting a quick drying liquid and a second head for jetting a conductive liquid are integrated with each other to move together in one printer. The inkjet printing device has an advantage in that as printing is continuously or simultaneously performed by the first head and the second head, a pattern formed by the first head and a pattern formed by the second head are unnecessary to be aligned in position with each other. That is, a position recognition device for aligning positions of two patterns or the like is not required.

The inkjet printing device includes: a transfer unit for transferring a substrate on which a conductive pattern is printed in one direction; a first head capable of reciprocatingly moving in a vertical direction at a front end in a movement direction of the substrate to jet the quick drying liquid; a light irradiation unit disposed adjacent to each of front and rear portions of the first head; and a second head disposed at a rear end in the movement direction of the substrate to reciprocatingly move in a direction perpendicular to the movement direction of the substrate, thereby jetting the conductive liquid.

FIGS. 6 and 7 are plan configuration views illustrating a schematic configuration of the inkjet printing device for realizing the method for printing a micro line pattern using inkjet printing according to the present invention.

First, the configuration of the inkjet printing device in FIG. 6 will be described.

The substrate transfer unit (transfer unit) linearly transfers the substrate along Y1 stage.

The first head, the light irradiation unit, the second head, an ink droplet precision measuring camera, and a substrate height measuring unit are installed on Z stage capable of vertically moving are installed, and the Z stage is capable of linearly moving along X stage.

For example, a moving block capable of linearly moving on the X stage may be provided, and the Z stage may be provided to the moving block to vertically move along the moving block.

The vertical movement of the Z stage and the linear movement of the moving block may be performed by a driving unit such as a linear motor and a linear guide.

The light irradiation unit is provided to each of the front and rear portions of the first head with respect to the movement direction of the substrate, and assembled on the Z stage to move together with the first head, thereby moving together with the driving unit for transferring the first head.

The second head is also assembled on the Z stage to move together with the driving unit for transferring the first head.

As described above, the first head, the light irradiation unit, and the second head are assembled to the Z stage to move together by one driving unit.

On the other hand, Y2 stage is provided next to the Y1 stage in parallel to each other, and a substrate for ink droplet precision measurement, on which an ink droplet is deposited to measure a precision of an ink droplet jetted from each of the first head and the second head, is provided on the Y2 stage.

Also, a head maintenance unit for maintaining the first and second heads is provided on the Y2 stage.

Also, an ink droplet sphere formation height measuring camera for measuring a sphere formation height of an ink droplet jetted from each of the first head and the second head is provided on the Y2 stage.

All of the ink droplet precision measuring substrate, the head maintenance unit, and the ink droplet sphere formation height measuring camera are assembled into one body and linearly move along the Y2 stage.

Next, the configuration of the inkjet printing device in FIG. 7 will be described.

The substrate transfer unit (transfer unit) linearly transfers a substrate along the Y1 stage.

A first head, a light irradiation unit, an ink droplet precision measuring camera, and a substrate height measuring unit are installed on Z1 stage capable of vertically moving, and the Z1 stage is capable of linearly moving along X1 stage.

For example, a moving block capable of linearly moving on the X1 stage may be provided, and the Z1 stage may be provided to the moving block to vertically move along the moving block.

The vertical movement of the Z1 stage and the linear movement of the moving block may be performed by a driving unit such as a linear motor and a linear guide.

The second head, the ink droplet precision measuring camera, and the substrate height measuring unit are installed on Z2 stage capable of vertically moving, and the Z2 stage is capable of linearly moving along X2 stage.

For example, a moving block capable of linearly moving on the X2 stage may be provided, and the Z2 stage may be provided to the moving block to vertically move along the moving block.

The vertical movement of the Z2 stage and the linear movement of the moving block may be performed by a driving unit such as a linear motor and a linear guide.

That is, the first head and the second head may individually move to a left side or a right side.

On the other hand, Y2 stage is provided next to the Y1 stage in parallel to each other, and a substrate for ink droplet precision measurement, on which an ink droplet is deposited to measure a precision of an ink droplet jetted from the first head, and a substrate for ink droplet precision measurement, on which an ink droplet is deposited to measure a precision of an ink droplet jetted from the second head, are provided on the Y2 stage.

Also, a first head maintenance unit for maintaining the first head and a second head maintenance unit for maintaining the second head are provided on the Y2 stage.

Also, a first ink droplet sphere formation height measuring camera for measuring a sphere formation height of an ink droplet jetted from the first head and a second ink droplet sphere formation height measuring camera for measuring a sphere formation height of an ink droplet jetted from the second head are provided on the Y2 stage.

The substrate for first ink droplet precision measurement, the first head maintenance unit, the first ink droplet sphere formation height measuring camera may be assembled into one body to linearly move together with the Y2 stage.

The substrate for second ink droplet precision measurement, the second head maintenance unit, the second ink droplet sphere formation height measuring camera may be assembled into one body to linearly move together with the Y2 stage.

Preferably, the above-described inkjet printing device is installed in an enclosed space having a helium gas atmosphere, and the process of forming the micro bump by the quick drying liquid that is inkjet-printed from the first head and the process of forming the conductive pattern by the conductive liquid that is inkjet-printed between the micro bumps by the second head are performed under the helium gas atmosphere.

Since helium has a density (0.1785 kg/m³) that is about 15% of a density (1.2 kg/m³) of air, a terminal velocity of the ink droplet should be increased. Particularly, the helium atmosphere may reduce air (gas) resistance to maintain a sufficient jetting speed and traveling longer distance although an ink droplet having a size of about 0.6 pl or less is jetted due to the less air resistance by a low molecular weight of helium.

According to the above-descried configuration of the inkjet printing device, the bump forming process is performed by the first head, the pattern printing process is performed by the second head, and the gelling of the photocurable ink is performed by the light irradiation unit.

Particularly, the bump forming process is performed such that the quick drying liquid is deposited on the substrate in a state of being inkjet-printed by the first head and then gelled by light irradiated from the light irradiation unit, to form the micro bump.

Also, the pattern printing process is performed such that the conductive liquid is jetted between the micro bumps by the second head to print the conductive pattern.

While the quick drying liquid is inkjet-printed by the first head, at the same time, the conductive liquid may be jetted by the second head. Thus, the micro bump and the conductive pattern may be formed at the same time.

Although one inkjet printing device including all of the first head and the second head is exemplarily described, two step printing may be performed by using a manufacturing line including one inkjet printing device including a first head and another inkjet printing device including a second head, which are separately provided, and a substrate transfer unit provided therebetween.

Here, in case of the two step printing, a unit for precise position recognition mark may be additionally required to transfer the substrate between two inkjet printing devices and precisely align a pattern printed on the transferred substrate to an exact position.

While the present invention has been particularly shown and described with reference to the accompanying drawings according to exemplary embodiments, it will be understood by those of ordinary skill in the art that various changes in form and details may be made therein without departing from the spirit and scope of the present invention as defined by the following claims. Hence, the real protective scope of the present invention shall be determined by the technical scope of the accompanying claims.

1. A method for printing a micro line pattern using inkjet printing, the method comprising:
a bump forming process for forming a micro bump that sections a predetermined conductive pattern by inkjet-printing a quick drying liquid on a substrate; and
a pattern printing process for printing a conductive pattern according to the predetermined conductive pattern by inkjet-printing a conductive liquid on an area sectioned by the micro bump.

2. The method of claim 1, wherein the quick drying liquid is photocurable ink that is inkjet-printed and then gelled by light.

3. The method of claim 1, wherein the quick drying liquid is hot melt ink that is inkjet-printed and then gelled by phase change due to a temperature difference.

4. The method of claim 1, wherein the quick drying liquid has a hydrophobic surface characteristic after dried.

5. The method of claim 1, wherein a surface of the substrate is hydrophobic-treated.

6. The method of claim 1, wherein the bump forming process increases a height of the micro bump by repeatedly inkjet-printing the quick drying liquid.

7. The method of claim 1, wherein the pattern printing process increases a height of the conductive pattern by repeatedly inkjet-printing the conductive liquid.

8. The method of claim 1, wherein each of the inkjet-printing of the quick drying liquid in the bump forming process and the inkjet-printing of the conductive liquid in the pattern printing process is performed by a drop on demand (DOD) inkjet printing method.

9. The method of claim 1, further comprising a bump removing process for removing the micro bump formed in the bump forming process after the pattern printing process.

10. The method of claim 2, wherein the bump forming process and the pattern printing process are performed by an inkjet printing device comprising: a transfer unit configured to transfer the substrate in one direction; a first head configured to reciprocatingly move in a vertical direction at a front end of a movement direction of the substrate to jet the quick drying liquid; a light irradiation unit installed adjacent to the first head; and a second head installed at a rear end of the movement direction of the substrate to reciprocatingly move in a direction perpendicular to the movement direction of the substrate, thereby jetting the conductive liquid,
wherein the bump forming process is performed such that the quick drying liquid is deposited on the substrate in a state of being inkjet-printed by the first head and then gelled by light irradiated from the light irradiation unit, to form the micro bump,
the pattern printing process is performed such that the conductive liquid is inkjet-printed between the micro bumps by the second head, to from the conductive pattern, and
the micro bump and the conductive pattern are printed at the same time.

11. The method of claim 10, wherein the first head and the light irradiation unit are integrated with each other to move together, and the first head, the light irradiation unit, and the second head are integrated with each other to move together.

12. The method of claim 10, wherein the inkjet printing device is installed in a closed space having a helium gas atmosphere, and the process of forming the micro bump by the quick drying liquid that is inkjet-printed from the first head and the process of forming the conductive pattern by the conductive liquid that is inkjet-printed between the micro bumps by the second head are performed under the helium gas atmosphere.
